(19) United States
(12) Patent Application Publication
(10) Pub. No.: US 2013/0328628 A1
(43) Pub. Date: Dec. 12, 2013

(54) AMPLIFIER CIRCUITS AND MODULATION SIGNAL GENERATING CIRCUITS THEREIN

(71) Applicant: Coretex Technology Corporation, New Taipei City (TW)

(72) Inventors: Wei-Zen CHEN, New Taipei City (TW); Chun-Pao LIN, New Taipei City (TW)

(73) Assignee: Coretex Technology Corporation, New Taipei City (TW)

(21) Appl. No.: 13/966,739

(22) Filed: Aug. 14, 2013

Related U.S. Application Data
(63) Continuation-in-part of application No. 13/563,352, filed on Jul. 31, 2012.

(30) Foreign Application Priority Data
Aug. 1, 2011 (TW) 100127174

(51) Int. Cl. H03F 3/217; H03K 7/08

(52) U.S. Cl. CPC H03F 3/2178; H03K 7/08
USPC 330/251; 332/109

(57) ABSTRACT

An amplifier circuit includes a modulation signal generating circuit, a driving stage circuit and an output stage circuit. The modulation signal generating circuit generates a pair of modulation signals according to a pair of differential input signals and a plurality of clock signals. The driving stage circuit generates a pair of driving signals according to the pair of modulation signals. The output stage circuit generates a pair of amplified output signals according to the pair of driving signals.

### CROSS REFERENCE TO RELATED APPLICATIONS

This application is a continuation-in-part (CIP) of U.S. patent application entitled “Amplifier circuits and modulation signal generating circuits therein,” Ser. No. 13/563,352 filed on Jul. 31, 2012, which claims priority of Taiwan Patent Application No. 100127174, filed on Aug. 1, 2011. The entire contents of which are hereby incorporated by reference.

### BACKGROUND OF THE INVENTION

1. Field of the Invention

The invention relates to an amplifier circuit, and more particularly to a two-order amplifier circuit with high stability and low signal distortion.

2. Description of the Related Art

Along with the developments in portable electronic technology, a variety of related products (such as the cell phone, personal digital assistance, tablet computer, or others) are becoming increasingly diverse. In addition, the multimedia streaming service has become one of the essential functions that are commonly provided by the portable electronic devices. Therefore, a high efficiency and low power consumption power amplifier is highly required by the portable electronic devices. In recent years, the class D amplifier has replaced the class AB amplifier and become a preferred choice as an audio power amplifier due to its merits of having a small circuit area and a 90% high amplifying efficiency. The class D amplifier is especially preferable for small sized portable electronic devices.

The class D amplifier is also called a digital power amplifier, which can output digitalized and amplified signals by modulating and amplifying the input analog signals. FIG. 1 shows a basic circuit diagram of a class D amplifier, in which the input signal Vin is modulated by the PWM (Pulse Width Modulation) modulator as the digital signals. The digital signals are then amplified by the power transistors Q1 and Q2, and the amplified digital signals are filtered by a low pass filter so as to filter out the original input audio signal to be played by the loud speaker.

Because the inputs of the power transistors are digital signals, the power transistors Q1 and Q2 work in the saturated or cut-off regions. Therefore, the power consumption of the power transistors Q1 and Q2 is very small, which may improve the overall efficiency of the power amplifier and reduce the area required by the heat dissipation devices. For these reasons, the circuit area of the class D power amplifier can be greatly reduced. In addition, the amplifying efficiency of a class AB amplifier is only 50%, while the amplifying efficiency of a class D amplifier can be as high as 90%, or even close to 100%. Thus, the class D amplifier has become commonly used in the audio power amplifier field.

Because probable electronic devices are usually used very close to a human body, the Electromagnetic Disturbance (EMI) generated by the probable electronic device must meet statutory standards and should be as small as possible.

Therefore, a two-order amplifier circuit with high stability and low signal distortion, which can reduce EMI and reduce the distortion in the amplified signals, is highly required.

### BRIEF SUMMARY OF THE INVENTION

Amplifier circuits and modulation signal generating circuits are provided. An exemplary embodiment of an amplifier circuit comprises a modulation signal generating circuit, a driving stage circuit and an output stage circuit. The modulation signal generating circuit generates a pair of modulation signals according to a pair of differential input signals and a plurality of clock signals. The driving stage circuit generates a pair of driving signals according to the pair of modulation signals. The output stage circuit generates a pair of amplified output signals according to the pair of driving signals.

An exemplary embodiment of a modulation signal generating circuit comprises an integration circuit, a comparator circuit and a logic circuit. The integration circuit comprises a plurality of hierarchically connected integrators to form a plurality of integrating paths for generating a plurality of pairs of integration signals according to a pair of differential input signals and a plurality of clock signals. The comparator circuit compares the pairs of integration signals to generate a pair of comparison signals. The logic circuit generates a pair of modulation signals according to logic operation results of the pair of comparison signals.

Another exemplary embodiment of a modulation signal generating circuit comprises a first order integration circuit, a second order integration circuit, a comparator circuit and a logic circuit. The first order integration circuit generates a first pair of integration signals according to a pair of differential input signals. The second order integration circuit generates a second pair of integration signals according to the first pair of integration signals and a plurality of clock signals. The comparator circuit generates a pair of comparison signals according to the first and the second pair of integration signals. The logic circuit generates a pair of modulation signals according to logic operation results of the pair of comparison signals.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a basic circuit diagram of a class D amplifier;

FIG. 2 is a block diagram of an amplifier circuit according to an embodiment of the invention;

FIG. 3 shows the waveforms of the clock signals according to an embodiment of the invention;

FIG. 4 shows a detailed circuit diagram of the amplifier circuit according to an embodiment of the invention;

FIG. 5A shows the equivalent logic gates for a NOR gate;

FIG. 5B shows the equivalent logic gates for a AND gate;

FIG. 6A shows exemplary waveforms of the second pair of integration signals according to an embodiment of the invention;

FIG. 6B shows exemplary waveforms of the third pair of integration signals according to an embodiment of the invention;

FIG. 7A shows exemplary waveform of comparison signal S_{Cmp1} according to an embodiment of the invention;

FIG. 7B shows exemplary waveform of comparison signal S_{Cmp2} according to an embodiment of the invention;

FIG. 8A shows exemplary waveform of modulation signal S_{Mod1} according to an embodiment of the invention;

FIG. 8B shows exemplary waveform of modulation signal S_{Mod2} according to an embodiment of the invention;

FIG. 9A shows exemplary waveforms of the second pair of integration signals according to another embodiment of the invention;

FIG. 9B shows exemplary waveforms of the third pair of integration signals according to another embodiment of the invention;

FIG. 10A shows exemplary waveform of the comparison signal S_{Cmp1} generated based on the integration signals as shown in FIG. 9A;

FIG. 10B shows exemplary waveform of the comparison signal S_{Cmp2} generated based on the integration signals as shown in FIG. 9B;

FIG. 11A shows exemplary waveform of modulation signal S_{Mod1} according to another embodiment of the invention;

FIG. 11B shows exemplary waveform of modulation signal S_{Mod2} according to another embodiment of the invention;

FIG. 12A shows exemplary waveforms of the second pair of integration signals according to yet another embodiment of the invention;

FIG. 12B shows exemplary waveforms of the third pair of integration signals according to yet another embodiment of the invention;

FIG. 13A shows exemplary waveform of the comparison signal S_{Cmp1} generated based on the integration signals as shown in FIG. 12A;

FIG. 13B shows exemplary waveform of the comparison signal S_{Cmp2} generated based on the integration signals as shown in FIG. 12B;

FIG. 14A shows exemplary waveform of modulation signal S_{Mod1} according to another embodiment of the invention;

FIG. 14B shows exemplary waveform of modulation signal S_{Mod2} according to another embodiment of the invention;

FIG. 15A shows exemplary waveforms of the integration signals generated based on a pair of clock signals according to an embodiment of the invention;

FIG. 15B shows exemplary waveforms of the integration signals generated based on a clock signal and a reference voltage according to another embodiment of the invention;

FIG. 16 shows a detailed circuit diagram of the amplifier circuit according to another embodiment of the invention;

FIG. 17 shows a detailed circuit diagram of the amplifier circuit according to yet another embodiment of the invention;

FIG. 18 shows a detailed circuit diagram of the amplifier circuit according to yet another embodiment of the invention;

FIG. 19 shows a detailed circuit diagram of the amplifier circuit according to yet another embodiment of the invention;

FIG. 20 is a block diagram of an amplifier circuit according to another embodiment of the invention;

FIG. 21 shows a detailed circuit diagram of the amplifier circuit according to yet another embodiment of the invention;

FIG. 22A shows exemplary waveforms of the second pair of integration signals according to another embodiment of the invention;

FIG. 22B shows exemplary waveforms of the first pair of integration signals according to another embodiment of the invention;

FIG. 23A shows exemplary waveform of comparison signal S_{Cmp1} according to another embodiment of the invention;

FIG. 23B shows exemplary waveform of comparison signal S_{Cmp2} according to another embodiment of the invention;

FIG. 24A shows exemplary waveform of modulation signal S_{Mod1} according to another embodiment of the invention;

FIG. 24B shows exemplary waveform of modulation signal S_{Mod2} according to another embodiment of the invention;

FIG. 25A shows exemplary waveforms of the second pair of integration signals according to another embodiment of the invention;

FIG. 25B shows exemplary waveforms of the first pair of integration signals according to another embodiment of the invention;

FIG. 26A shows exemplary waveform of comparison signal S_{Cmp1} according to another embodiment of the invention;

FIG. 26B shows exemplary waveform of comparison signal S_{Cmp2} according to another embodiment of the invention;

FIG. 27A shows exemplary waveform of modulation signal S_{Mod1} according to another embodiment of the invention;

FIG. 27B shows exemplary waveform of modulation signal S_{Mod2} according to another embodiment of the invention;

FIG. 28A shows exemplary waveforms of the second pair of integration signals according to another embodiment of the invention;

FIG. 28B shows exemplary waveforms of the first pair of integration signals according to another embodiment of the invention;

FIG. 29A shows exemplary waveform of comparison signal S_{Cmp1} according to another embodiment of the invention;

FIG. 29B shows exemplary waveform of comparison signal S_{Cmp2} according to another embodiment of the invention;

FIG. 30A shows exemplary waveform of modulation signal S_{Mod1} according to another embodiment of the invention; and

FIG. 30B shows exemplary waveform of modulation signal S_{Mod2} according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

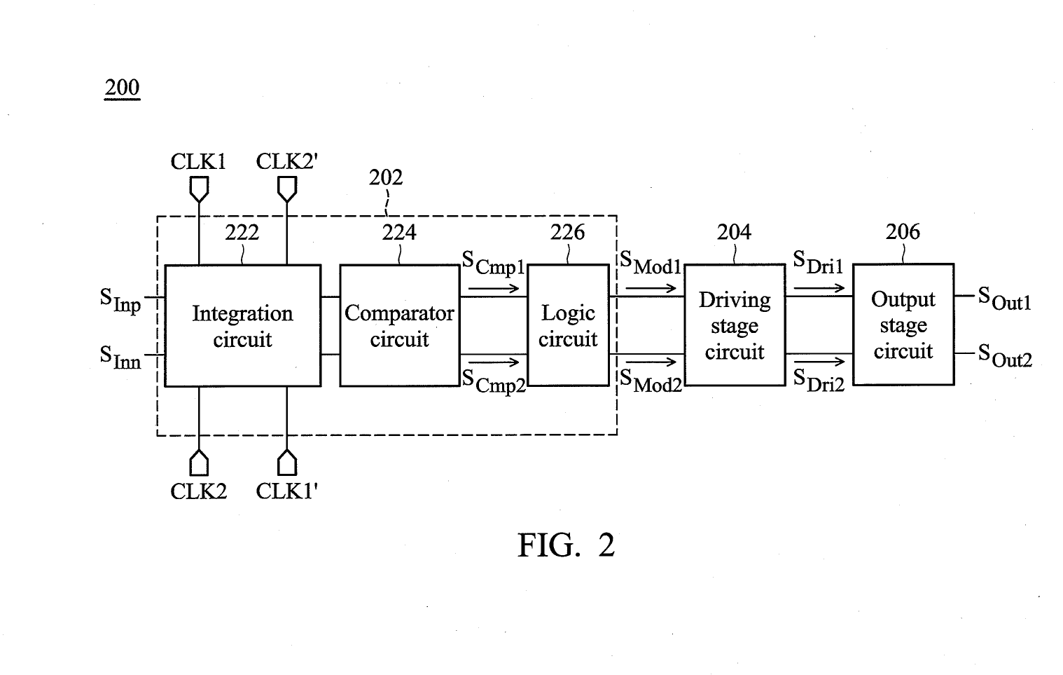

FIG. 2 is a block diagram of an amplifier circuit according to an embodiment of the invention. The proposed amplifier circuit may be a two-order class BD amplifier, which comprises the characteristics of both of the class B and class D amplifiers and can greatly reduce the EMI of the amplified output signals and also reduce the distortion in the amplified output signals. As shown in FIG. 2, the amplifier circuit 200 comprises a modulation signal generating circuit 202, a driving stage circuit 204 and an output stage circuit 206. The modulation signal generating circuit 202 generates a pair of modulation signals S_{Mod1} and S_{Mod2} according to a pair of differential input signals S_{Inp} and S_{Inn} and a plurality of clock signals CLK1/CLK1′ and CLK2/CLK2′. The driving stage circuit 204 generates a pair of driving signals S_{Dri1} and S_{Dri2} according to the pair of modulation signals S_{Mod1} and S_{Mod2}, respectively. The output stage circuit 206 generates a pair of amplified output signals S_{Out1} and S_{Out2} according to the pair of driving signals S_{Dri1} and S_{Dri2}, respectively.

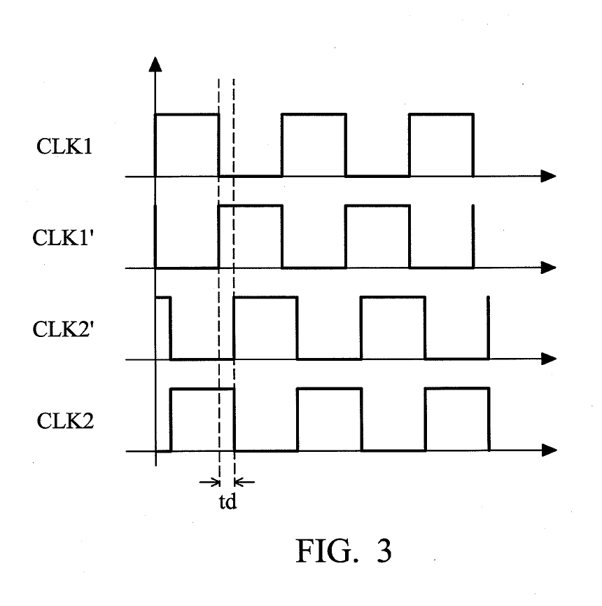

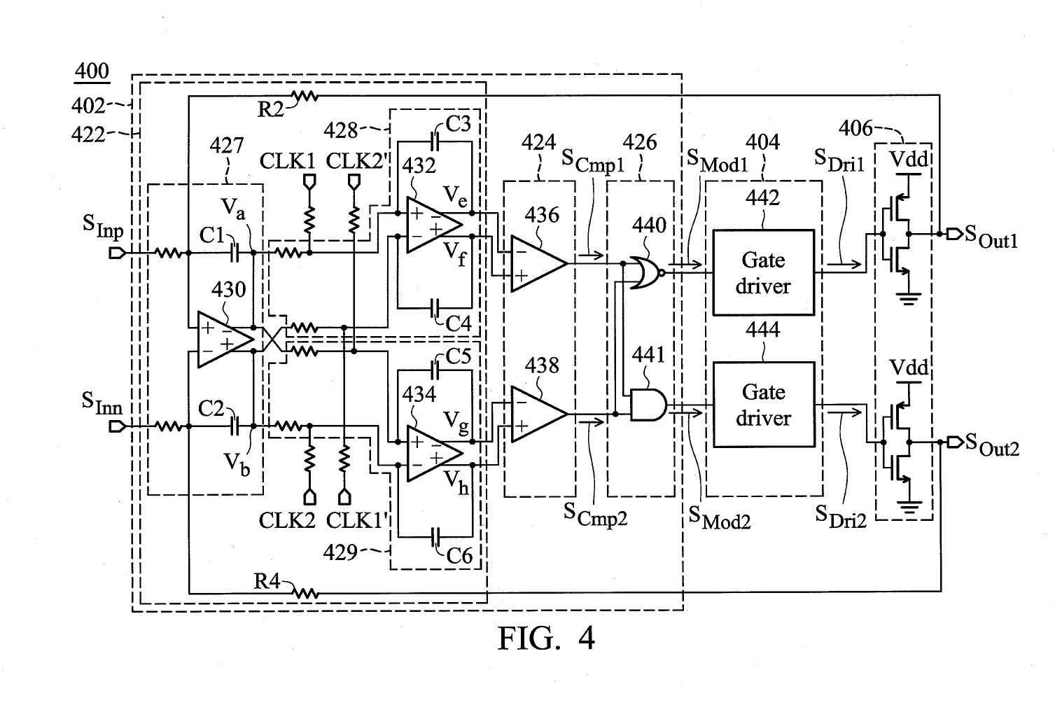

According to an embodiment of the invention, there is a phase difference td between the clock signals CLK1 and CLK2. FIG. 3 shows the waveforms of the clock signals according to an embodiment of the invention. The clock signal CLK1′ is complementary to the clock signal CLK1, and the clock signal CLK2′ is complementary to the clock signal CLK2. There is a phase difference td between the clock signals CLK1 and CLK2 and there is also a phase difference td between the clock signals CLK1′ and CLK2′. According to an embodiment of the invention, the phase difference td may be arbitrarily determined as a value greater than a sum of an overall propagation delay of the amplifier circuit 200 and a dead time of the output stage circuit 204. The overall propagation delay may be determined by the electronic properties of the elements comprised in the amplifier circuit 200, and the dead time may be determined by the ON/OFF time of the power transistors comprised in the output stage circuit 206 (reference may be made to FIG. 4).

Referring back to FIG. 2, according to an embodiment of the invention, the modulation signal generating circuit 202 may comprise an integration circuit 222, a comparator circuit 224 and a logic circuit 226. The integration circuit 222 generates a plurality of pairs of integration signals according to the pair of differential input signals S_{Inp} and S_{Inn} and the clock signals CLK1/CLK1′ and CLK2/CLK2′. The comparator circuit 224 compares the pairs of integration signals to generate a pair of comparison signals S_{Cmp1} and S_{Cmp2}. The logic circuit 226 generates the pair of modulation signals S_{Mod1} and S_{Mod2} according to logic operation results of the pair of comparison signals S_{Cmp1} and S_{Cmp2}.

FIG. 4 shows a detailed circuit diagram of the amplifier circuit according to an embodiment of the invention. The amplifier circuit 400 comprises a modulation signal generating circuit 402, a driving stage circuit 404 and an output stage circuit 406. The modulation signal generating circuit 402 generates a pair of modulation signals S_{Mod1} and S_{Mod2} according to a pair of differential input signals S_{Inp} and S_{Inn} and the clock signals CLK1/CLK1′ and CLK2/CLK2′. The driving stage circuit 404 generates a pair of driving signals S_{Dri1} and S_{Dri2} according to the pair of modulation signals S_{Mod1} and S_{Mod2}, respectively. The output stage circuit 406 generates a pair of amplified output signals S_{Out1} and S_{Out2} according to the pair of driving signals S_{Dri1} and S_{Dri2}, respectively.

As shown in FIG. 4, the modulation signal generating circuit 402 comprises an integration circuit 422, a comparator circuit 424 and a logic circuit 426. The output stage circuit 406 comprises a plurality of power transistors. The driving stage circuit 404 comprises gate drivers 442 and 444 each being respectively coupled to a gate of the power transistors for driving the corresponding power transistors according to the driving signals S_{Dri1} and S_{Dri2}. According to an embodiment of the invention, the gate drivers 442 and 444 may be implemented by inverters.

The integration circuit 422 may comprise a plurality of hierarchically connected integrators to form a plurality of integrating paths for generating a plurality of pairs of integration signals according to the pair of differential input signals and the clock signals. According to an embodiment of the invention, the integration circuit 422 comprises at least a pair of feedback resistors R2 and R4, each being respectively coupled between a pair of output nodes and a pair of input nodes of the amplifier circuit 400, for feeding the pair of amplified output signals S_{Out1} and S_{Out2} (which may be regarded as a pair of feedback signals) back to the pair of input nodes of the amplifier circuit 400. The integration circuit 422 further comprises fully differential error amplifiers 430, 432 and 434. The fully differential error amplifiers 430, 432 and 434 accompanying with the feedback resistors R2 and R4 and the capacitors C1 and C2, C3 and C4, and C5 and C6 form a two-order integration circuit. The first order integration circuit comprises a first integrator 427, which is formed by the fully differential error amplifier 430 and corresponding capacitors and resistors, and the second order integration circuit comprises a second integrator 428 and a third integrator 429, which is respectively formed by the fully differential error amplifiers 432 and 434 and corresponding capacitors and resistors. Since the integrators 427, 428 and 429 are hierarchically connected, the first integrator 427 and the second integrator 428 together form a first two-order integrating path and the first integrator 427 and the third integrator 429 together form a second two-order integrating path

According to an embodiment of the invention, the first integrator is coupled to the pair of input nodes of the amplifier circuit 400 for generating a first pair of integration signals at a pair of differential output nodes Va and Vb according to the pair of differential input signals S_{Inp} and S_{Inn} and the pair of amplified output signals S_{Out1} and S_{Out2} which are fed back to the pair of input nodes. The second integrator is coupled to the pair of differential output nodes Va and Vb of the first integrator and corresponding clock input nodes for receiving the clock signals CLK1 and CLK1′, and generates a second pair of integration signals at a pair of differential output nodes Ve and Vf according to the first pair of integration signals and the clock signals CLK1 and CLK1′. The third integrator is also coupled to the pair of differential output nodes Va and Vb of the first integrator and corresponding clock input nodes for receiving the clock signals CLK2 and CLK2′, and generates a third pair of integration signals at a pair of differential output nodes Vg and Vh according to the first pair of integration signals and the clock signals CLK2 and CLK2′.

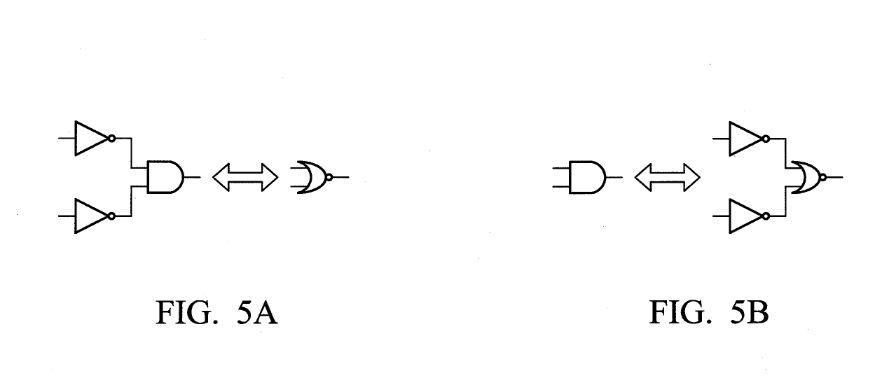

The comparator circuit 424 comprises comparators 436 and 438. The comparator 436 is coupled to the pair of differential output nodes Ve and Vf of the second integrator for comparing the second pair of integration signals to generate the comparison signal S_{Cmp1}. The comparator 438 is coupled to the pair of differential output nodes Vg and Vh of the third integrator for comparing the third pair of integration signals to generate the comparison signal S_{Cmp2}. The logic circuit 426 comprises a NOR gate 440 and an AND gate 441, for respectively performing logic operations on the comparison signals S_{Cmp1} and S_{Cmp2} to generate the modulation signals S_{Mod1} and S_{Mod2}. It should be noted that the invention should not be limited to the NOR gate and AND gate as shown in FIG. 4. FIG. 5A and FIG. 5B show the equivalent logic gates for the NOR gate and AND gate. In some embodiments of the invention, the NOR gate 440 and an AND gate 441 as shown in FIG. 4 may be replaced by the logic gates shown in FIG. 5A and FIG. 5B, or other logic gates. Therefore, the invention scope should not be limited to the NOR gate 440 and an AND gate 441 as shown in FIG. 4.

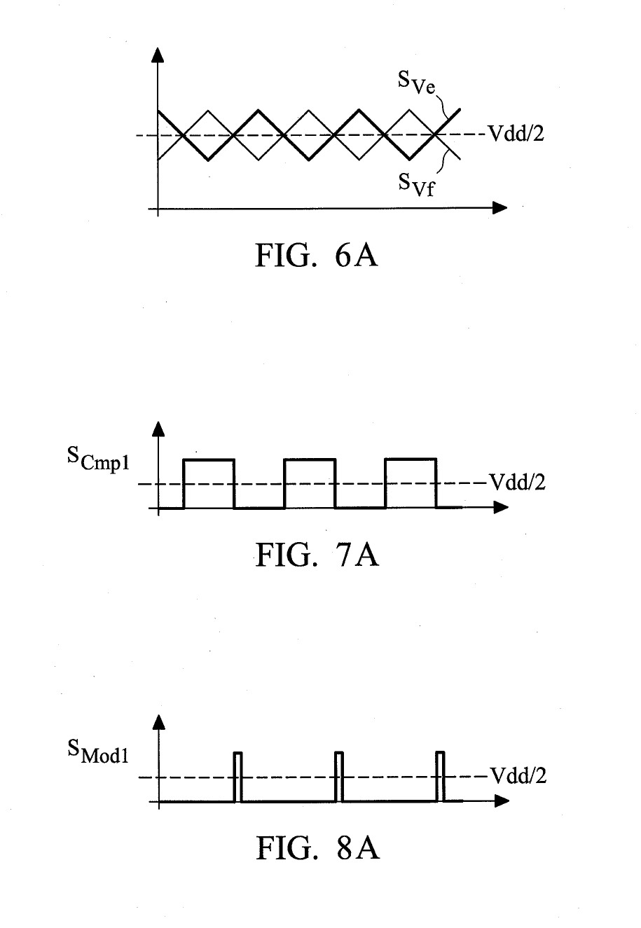

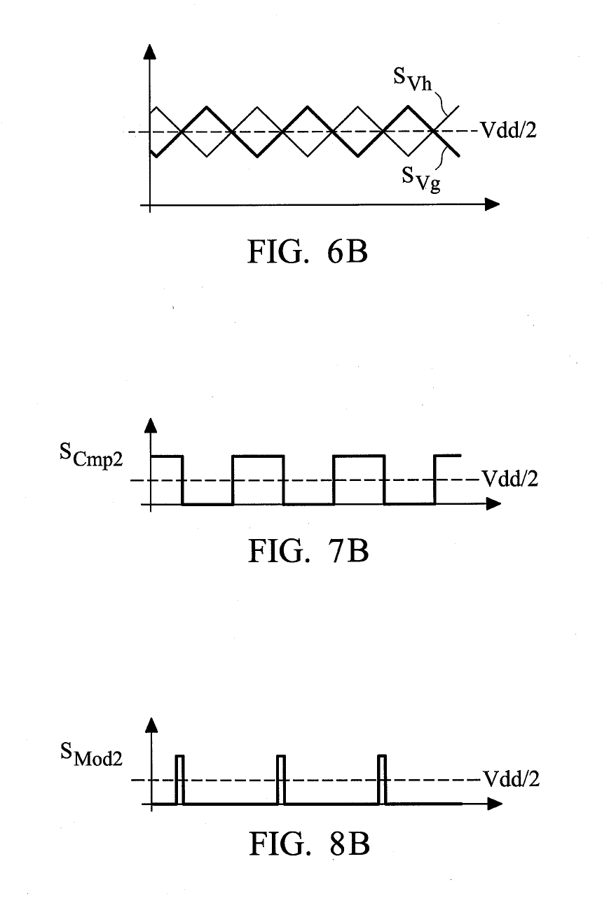

FIG. 6A shows exemplary waveforms of the second pair of integration signals S_{Ve} and S_{Vf} generated at the differential output nodes Ve and Vf according to an embodiment of the invention. FIG. 6B shows exemplary waveforms of the third pair of integration signals S_{Vg} and S_{Vh} generated at the differential output nodes Vg and Vh according to an embodiment of the invention. The second pair of integration signals S_{Ve} and S_{Vf} are the integration signals outputted from the differential output nodes Ve and Vf and the third pair of integration signals S_{Vg} and S_{Vh} are the integration signals outputted from the differential output nodes Vg and Vh. The comparators 436 and 438 respectively compares the levels of the integration signals S_{Ve} and S_{Vf}, and S_{Vg} and S_{Vh}, and generate the comparison signal S_{Cmp1} as shown in FIG. 7A and the comparison signal S_{Cmp2} as shown in FIG. 7B. The logic circuit performs NOR and AND logic operations on the comparison signals S_{Cmp1} and S_{Cmp2}, and obtains the modulation signal S_{Mod1} as shown in FIG. 8A and the modulation signal S_{Mod2} as shown in FIG. 8B.

According to an embodiment of the invention, FIG. 6 to FIG. 8 show the waveforms of output signals of each circuit when there is no alternating current (AC) signal input to the circuits, wherein no AC signal input means the level difference between the output signals at the differential output nodes Va and Vb is 0. As shown in FIG. 8A and FIG. 8B, when there is no AC signal input, both the modulation signals S_{Mod1} and S_{Mod2} comprise pulses which are very narrow in width.

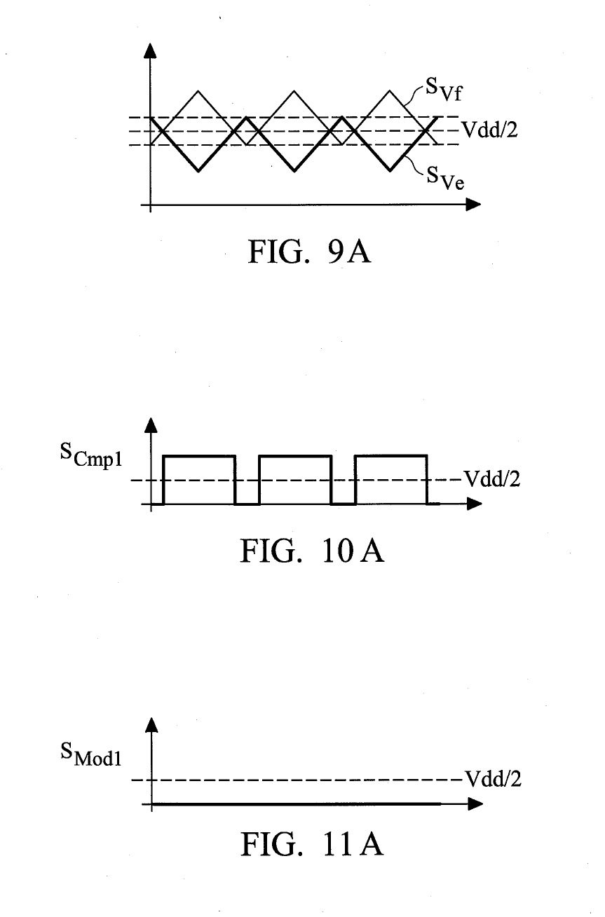

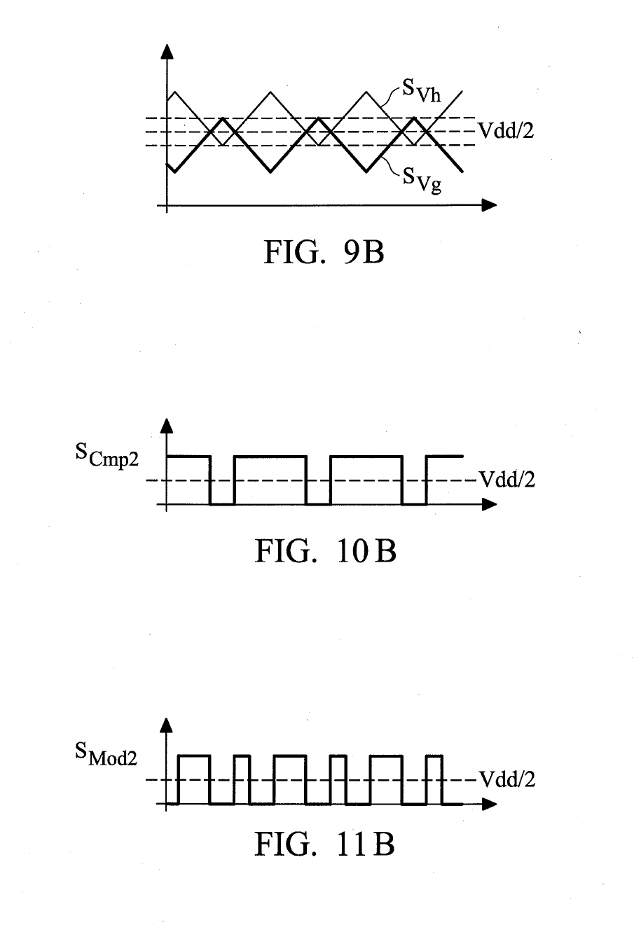

FIG. 9A shows exemplary waveforms of the second pair of integration signals S_{Ve} and S_{Vf} according to another embodiment of the invention. FIG. 9B shows exemplary waveforms of the third pair of integration signals S_{Vg} and S_{Vh} according to another embodiment of the invention. In this embodiment, there is an AC signal input to the circuits and a level of the output signal at the differential output node Va is greater than that at the differential output node Vb (in other words, the level difference between the output signals at the differential output nodes Va and Vb is greater than 0). FIG. 10A shows the waveform of the comparison signal S_{Cmp1} generated based on the integration signals S_{Ve} and S_{Vf} as shown in FIG. 9A. FIG. 10B shows the waveform of the comparison signal S_{Cmp2} generated based on the integration signals S_{Vg} and S_{Vh} as shown in FIG. 9B. Finally, the logic circuit performs NOR and AND logic operations on the comparison signals S_{Cmp1} and S_{Cmp2} and obtains the modulation signal S_{Mod1} as shown in FIG. 11A and the modulation signal S_{Mod2} as shown in FIG. 11B. As shown in FIG. 11A and FIG. 11B, when the level difference between the output signals at the differential output nodes Va and Vb is greater than 0, the modulation signal S_{Mod1} is always 0.

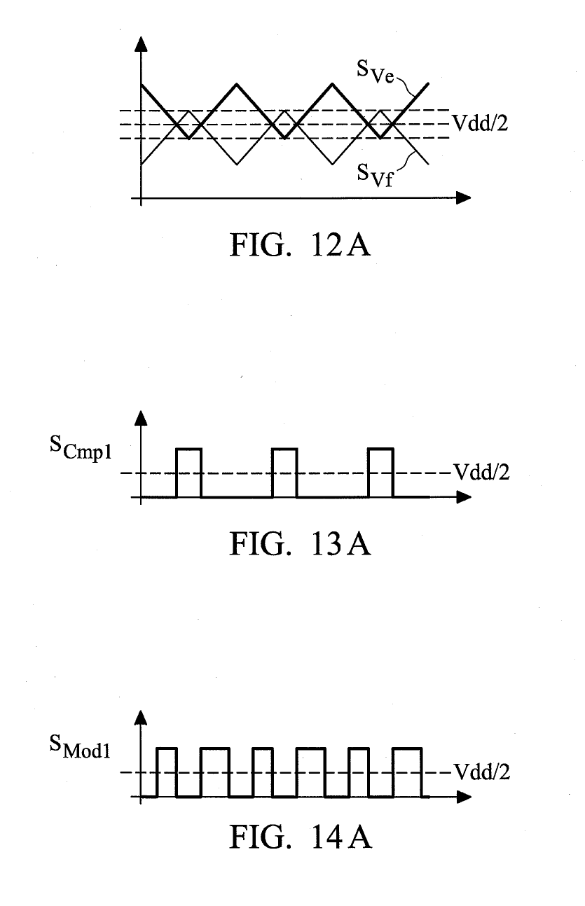

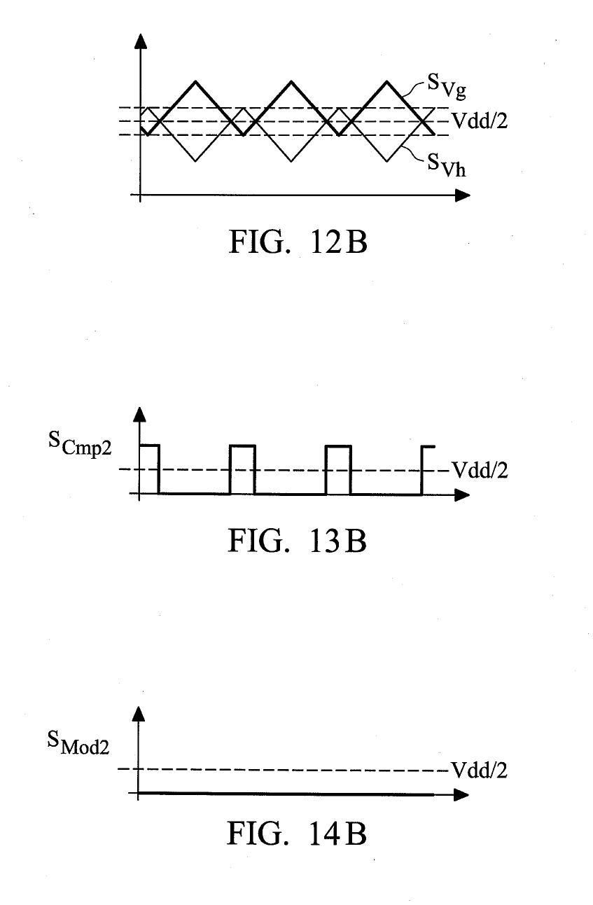

FIG. 12A shows exemplary waveforms of the second pair of integration signals S_{Ve} and S_{Vf} according to yet another embodiment of the invention. FIG. 12B shows exemplary waveforms of the third pair of integration signals S_{Vg} and S_{Vh} according to yet another embodiment of the invention. In this embodiment, there is an AC signal input to the circuits and a level of the output signal at the differential output node Va is smaller than that at the differential output node Vb (in other words, the level difference between the output signals at the differential output nodes Va and Vb is less than 0). FIG. 13A shows the waveform of the comparison signal S_{Cmp1} generated based on the integration signals S_{Ve} and S_{Vf} shown in FIG. 12A. FIG. 13B shows the waveform of the comparison signal S_{Cmp2} generated based on the integration signals S_{Vg} and S_{Vh} shown in FIG. 12B. Finally, the logic circuit performs NOR and AND logic operations on the comparison signals S_{Cmp1} and S_{Cmp2} and obtains the modulation signal S_{Mod1} as shown in FIG. 14A and the modulation signal S_{Mod2} as shown in FIG. 14B. As shown in FIG. 14A and FIG. 14B, when the level difference between the output signals at the differential output nodes Va and Vb is less than 0, the modulation signal S_{Mod2} is always 0.

From FIG. 8A and FIG. 8B, FIG. 11A and FIG. 11B and FIG. 14A and FIG. 14B, it can be noted that different from the pulse width modulation (PWM) signals outputted by the conventional class D amplifier, the modulation signals S_{Mod1} and S_{Mod2} outputted by the proposed amplifier circuit may comprise narrow pulses when there is no AC signal input, and one of them may always be 0 when there is any AC signal input. In this manner, the EMI of the amplified output signal can be greatly reduced while the signal level (i.e. strength) of the modulation signals can remain unchanged because the modulation signals can have a narrower pulse width than in a conventional class D amplifier, or can even be 0.

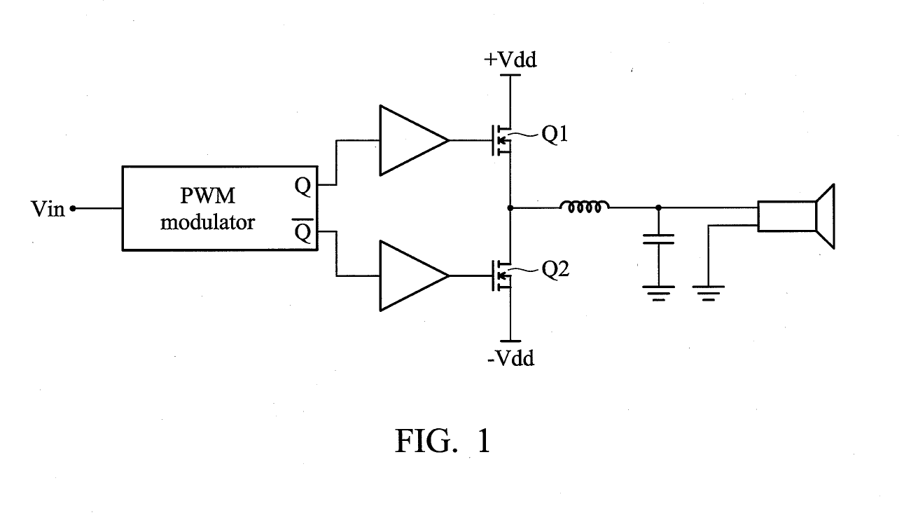

In addition, as shown in FIG. 1, the PWM modulator in the conventional class D amplifier requires an extra triangle wave generator to generate a triangle wave with a predetermined frequency. The triangle wave generator is generally not easy to design. However, as shown in FIG. 6A and FIG. 6B, FIG. 9A and FIG. 9B, and FIG. 12A and FIG. 12B, the triangle waves have been generated in the modulation procedure of the modulation signal generating circuit and have been carried onto the integration signals S_{Ve}, S_{Vf}, S_{Vg} and S_{Vg}. Therefore, in the proposed amplifier circuit, the extra triangle wave generator is not required. As long as the clock signals CLK1/CLK2 are input, the modulation signals can be generated.

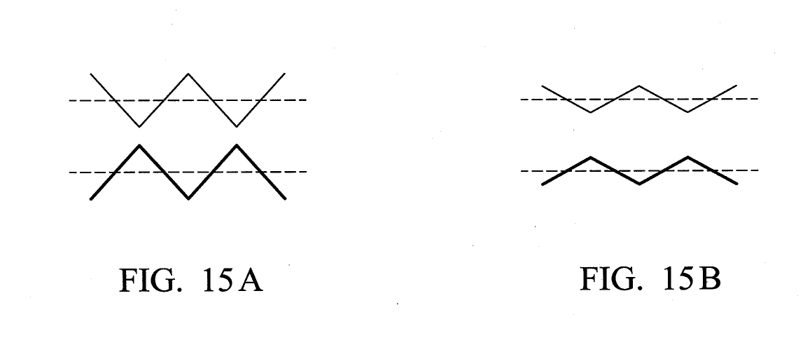

In the above-mentioned embodiments, the second order integration circuit (comprising the second integrator and the third integrator) generates the second pair and third pair integration signals S_{Ve}, S_{Vf}, S_{Vg} and S_{Vh} according to a pair of clock signals CLK1/CLK1′ and CLK2/CLK2′. According to another embodiment of the invention, one of the clock signals may also be replaced by a reference voltage, and a similar modulation result may be obtained. FIG. 15A shows exemplary waveforms of the integration signals generated based on a pair of clock signals according to an embodiment of the invention. FIG. 15B shows exemplary waveforms of the integration signals generated based on a clock signal and a reference voltage according to another embodiment of the invention, where the reference voltage may be designed as a half of the operation voltage Vdd of the amplifier circuit (that is, Vdd/2). Comparing the waveforms of the integration signals as shown in FIG. 15A and FIG. 15B, it can be noted that the difference is only in the amplitudes of the signal waveforms, where the integration signals generated based on the reference voltage have relatively smaller amplitudes.

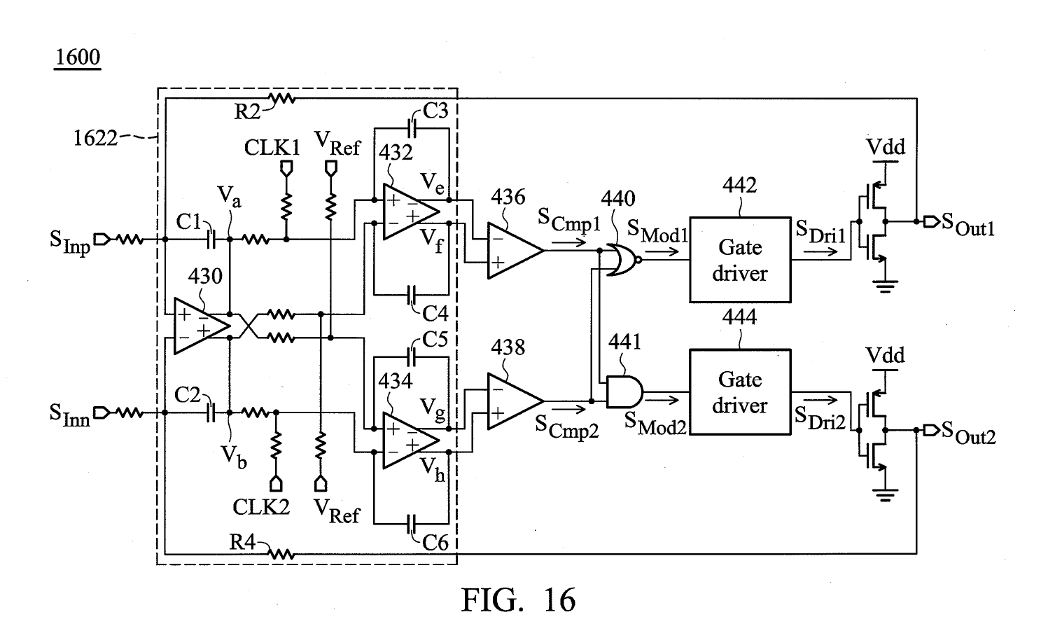

It is noted that based on the spirit of the invention, in the embodiment where one of the clock signals is replaced by the reference voltage V_{Ref}, the similar modulation results may be obtained as long as one input node of the second and third integrators is designed to receive the reference voltage V_{Ref} and the other one input node is designed to receive two of the clock signals CLK1, CLK1′, CLK2 and CLK2′, where there should be a phase difference td between the clock signals received by the second and third integrators. As previously described, the phase difference td may be arbitrarily determined as any number greater than a sum of the overall propagation delay of the amplifier circuit and the dead time of the output stage circuit. Therefore, the circuits shown in the following FIG. 16-FIG. 19 are just part of a variety of embodiments of the invention and the scope of the invention should not be limited thereto.

FIG. 16 shows a detailed circuit diagram of the amplifier circuit according to another embodiment of the invention. Most of the elements in the amplifier circuit 1600 shown in FIG. 16 are the same as the elements in the amplifier circuit 400 shown in FIG. 4. Therefore, details of the amplifier circuit may refer to FIG. 4, and are omitted here for brevity. In this embodiment, the integration circuit 1622 receives the clock signals CLK1 and CLK2 and the reference voltage V_{Ref}, wherein the second integrator generates the integration signals S_{Ve} and S_{Vf} according to the output signals of the first integrator, the reference voltage V_{Ref} and the clock signal CLK1, and the third integrator generates the integration signals S_{Vg} and S_{Vh} according to the output signals of the first integrator, the reference voltage V_{Ref} and the clock signal CLK2. The comparators 436 and 438 compare the levels of the integration signals S_{Ve} and S_{Vf} and S_{Vg} and S_{Vh} to generate the comparison signals S_{Cmp1} and S_{Cmp2,} respectively. The logic circuit performs logic operations on the comparison signals S_{Cmp1} and S_{Cmp2} to generate the modulation signals S_{Mod1} and S_{Mod2}.

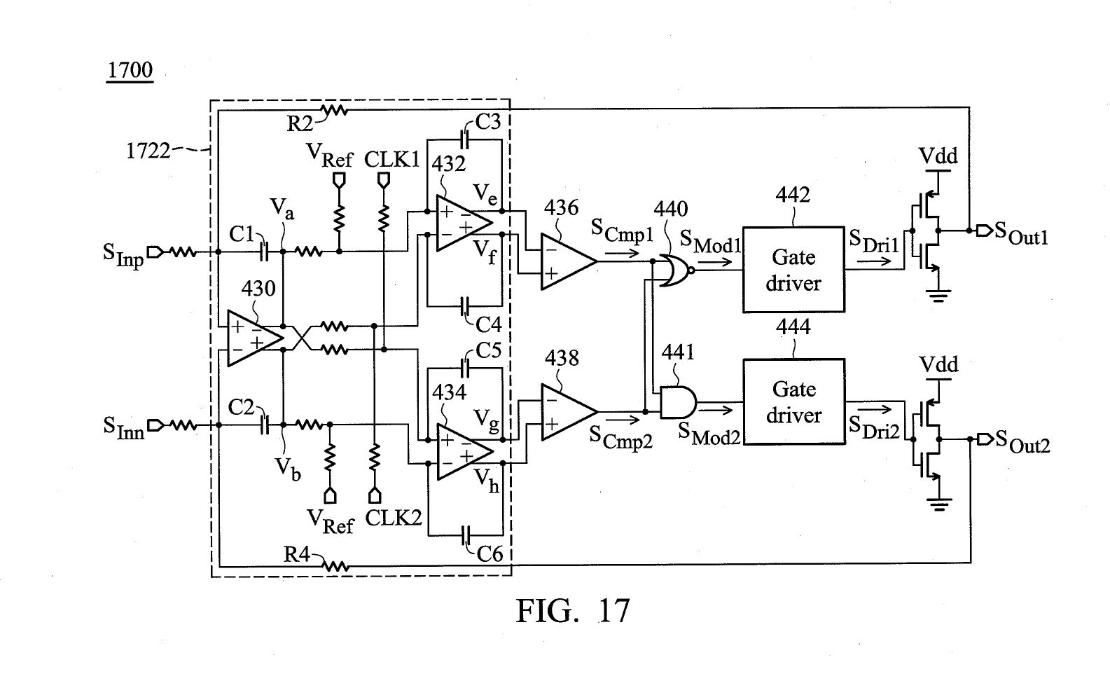

FIG. 17 shows a detailed circuit diagram of the amplifier circuit according to yet another embodiment of the invention. Most of the elements in the amplifier circuit 1700 shown in FIG. 17 are the same as the elements in the amplifier circuit 400 shown in FIG. 4. Therefore, details of the amplifier circuit may refer to FIG. 4, and are omitted here for brevity. In this embodiment, the integration circuit 1722 receives the clock signals CLK1 and CLK2 and the reference voltage V_{Ref}, wherein the second integrator generates the integration signals S_{Ve} and S_{Vf} according to the output signals of the first integrator, the reference voltage V_{Ref} and the clock signal CLK2, and the third integrator generates the integration signals S_{Vg} and S_{Vh} according to the output signals of the first integrator, the reference voltage V_{Ref} and the clock signal CLK1. The comparators 436 and 438 compare the levels of the integration signals S_{Ve} and S_{Vf} and S_{Vg} and S_{Vh} to generate the comparison signals S_{Cmp1} and S_{Cmp2}, respectively. The logic circuit performs logic operations on the comparison signals S_{Cmp1} and S_{Cmp2} to generate the modulation signals S_{Mod1} and S_{Mod2}.

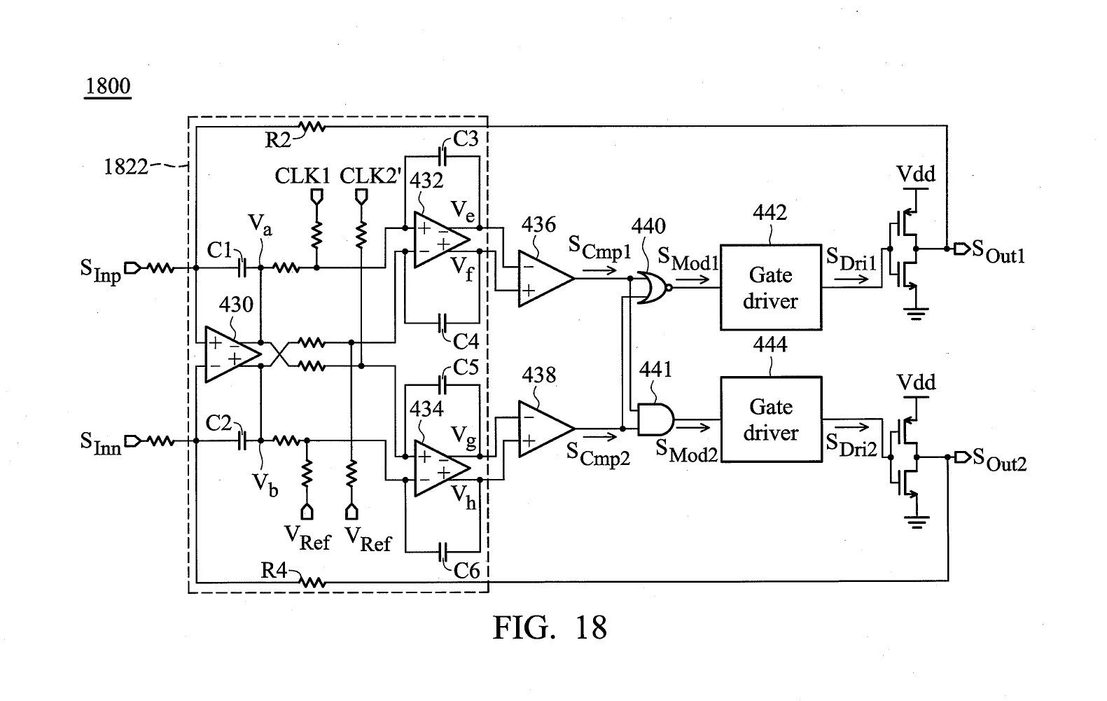

FIG. 18 shows a detailed circuit diagram of the amplifier circuit according to yet another embodiment of the invention. Most of the elements in the amplifier circuit 1800 shown in FIG. 18 are the same as the elements in the amplifier circuit 400 shown in FIG. 4. Therefore, details of the amplifier circuit may refer to FIG. 4, and are omitted here for brevity. In this embodiment, the integration circuit 1822 receives the clock signals CLK1 and CLK2′ and the reference voltage V_{Ref}, wherein the second integrator generates the integration signals S_{Ve} and S_{Vf} according to the output signals of the first integrator, the reference voltage V_{Ref} and the clock signal CLK1, and the third integrator generates the integration signals S_{Vg} and S_{Vh} according to the output signals of the first integrator, the reference voltage V_{Ref} and the clock signal CLK2′. The comparators 436 and 438 compare the levels of the integration signals S_{Ve} and S_{Vf} and S_{Vg} and S_{Vh} to generate the comparison signals S_{Cmp1} and S_{Cmp2}, respectively. The logic circuit performs logic operations on the comparison signals S_{Cmp1} and S_{Cmp2} to generate the modulation signals S_{Mod1} and S_{Mod2}.

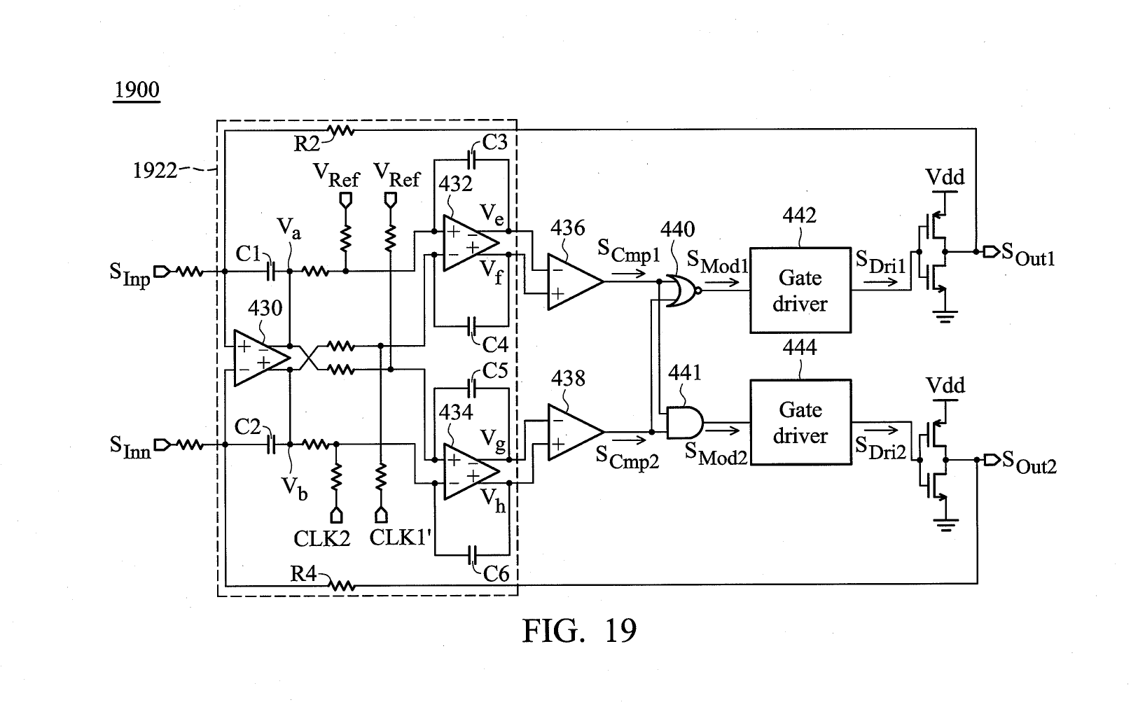

FIG. 19 shows a detailed circuit diagram of the amplifier circuit according to yet another embodiment of the invention. Most of the elements in the amplifier circuit 1900 shown in FIG. 19 are the same as the elements in the amplifier circuit 400 shown in FIG. 4. Therefore, details of the amplifier circuit may refer to FIG. 4, and are omitted here for brevity. In this embodiment, the integration circuit 1922 receives the clock signals CLK1′ and CLK2 and the reference voltage V_{Ref}, wherein the second integrator generates the integration signals S_{Ve} and S_{Vf} according to the output signals of the first integrator, the reference voltage V_{Ref} and the clock signal CLK1′, and the third integrator generates the integration signals S_{Vg} and S_{Vh} according to the output signals of the first integrator, the reference voltage V_{Ref} and the clock signal CLK2. The comparators 436 and 438 compare the levels of the integration signals S_{Ve} and S_{Vf} and S_{Vg} and S_{Vh} to generate the comparison signals S_{Cmp1} and S_{Cmp2}, respectively. The logic circuit performs logic operations on the comparison signals S_{Cmp1} and S_{Cmp2} to generate the modulation signals S_{Mod1} and S_{Mod2}.

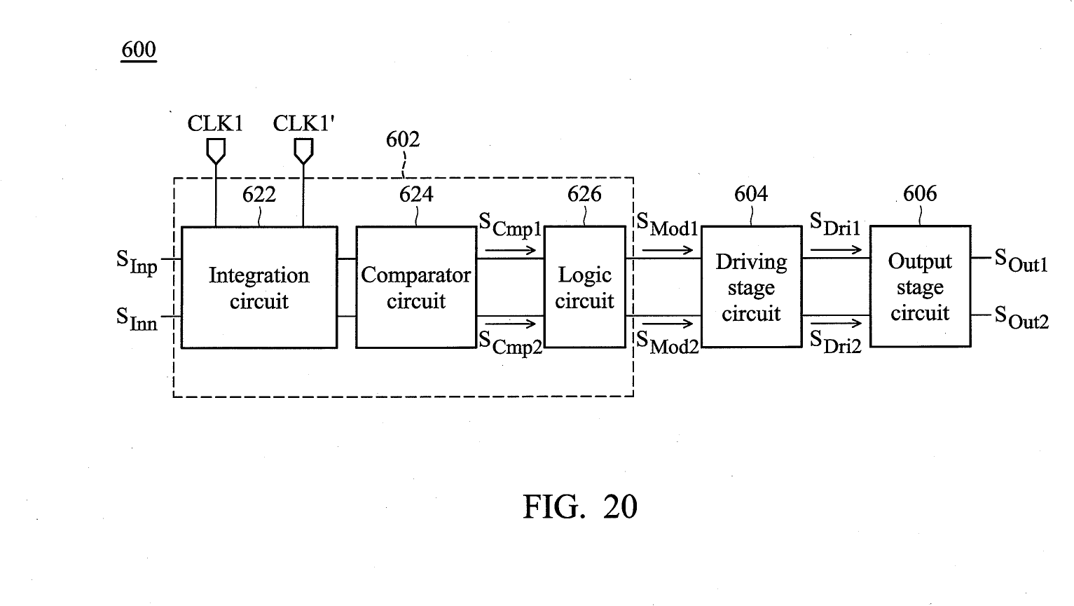

FIG. 20 is a block diagram of an amplifier circuit according to another embodiment of the invention. The proposed amplifier circuit may be a two-order class BD amplifier, which comprises the characteristics of both of the class B and class D amplifiers and can greatly reduce the EMI of the amplified output signals and also reduce the distortion in the amplified output signals. As shown in FIG. 20, the amplifier circuit 600 comprises a modulation signal generating circuit 602, a driving stage circuit 604 and an output stage circuit 606. The modulation signal generating circuit 602 generates a pair of modulation signals S_{Mod1} and S_{Mod2} according to a pair of differential input signals S_{Inp} and S_{Inn} and a plurality of clock signals CLK1 and CLK1′. The driving stage circuit 604 generates a pair of driving signals S_{Dri1} and S_{Dri2} according to the pair of modulation signals S_{Mod1} and S_{Mod2}, respectively. The output stage circuit 606 generates a pair of amplified output signals S_{Out1} and S_{Out2} according to the pair of driving signals S_{Dri1} and S_{Dri2}, respectively.

Note that comparing with the amplifier circuit 200 as shown in FIG. 2, the modulation signal generating circuit 602 receives only a pair of complementary clock signals CLK1 and CLK1′. The waveforms of the clock signals CLK1 and CLK1′ may refer to FIG. 3, and are omitted here for brevity.

Referring back to FIG. 20, according to an embodiment of the invention, the modulation signal generating circuit 602 may comprise an integration circuit 622, a comparator circuit 624 and a logic circuit 626. The integration circuit 622 generates a plurality of pairs of integration signals according to the pair of differential input signals S_{Inp} and S_{Inn} and the complementary clock signals CLK1 and CLK1′. The comparator circuit 624 compares the pairs of integration signals to generate a pair of comparison signals S_{Cmp1} and S_{Cmp2}. The logic circuit 626 generates the pair of modulation signals S_{Mod1} and S_{Mod2} according to logic operation results of the pair of comparison signals S_{Cmp1} and S_{Cmp2}.

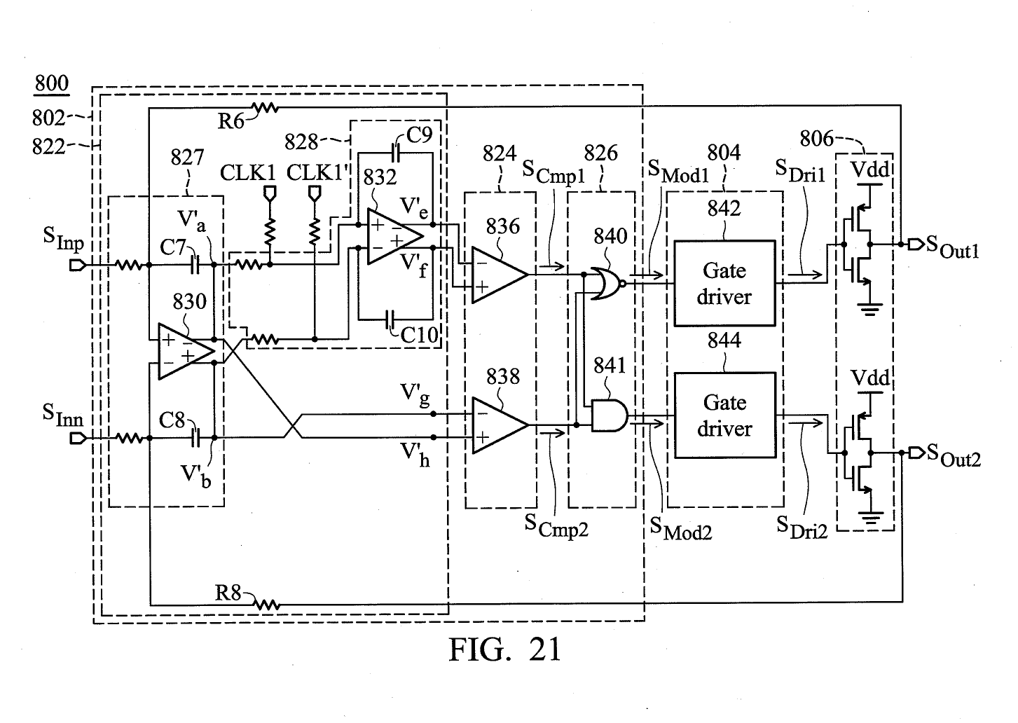

FIG. 21 shows a detailed circuit diagram of the amplifier circuit according to yet another embodiment of the invention. The amplifier circuit 800 comprises a modulation signal generating circuit 802, a driving stage circuit 804 ₛand an output stage circuit 806. The modulation signal generating circuit 802 generates a pair of modulation signals S_{Mod1} and S_{Mod2} according to a pair of differential input signals S_{Inp} and S_{Inn} and the complementary clock signals CLK1 and CLK1′. The driving stage circuit 804 generates a pair of driving signals S_{Dri1} and S_{Dri2} according to the pair of modulation signals S_{Mod1} and S_{Mod2}, respectively. The output stage circuit 806 generates a pair of amplified output signals S_{Out1} and S_{Out2} according to the pair of driving signals S_{Dri1} and S_{Dri2}, respectively.

As shown in FIG. 21, the modulation signal generating circuit 802 comprises an integration circuit 822, a comparator circuit 824 and a logic circuit 826. The output stage circuit 806 comprises a plurality of power transistors. The driving stage circuit 804 comprises gate drivers 842 and 844 each being respectively coupled to a gate of the power transistors for driving the corresponding power transistors according to the driving signals S_{Dri1} and S_{Dri2}. According to an embodiment of the invention, the gate drivers 842 and 844 may be implemented by inverters.

The integration circuit 822 may comprise a plurality of hierarchically connected integrators to form a plurality of integrating paths for generating a plurality of pairs of integration signals according to the pair of differential input signals and the clock signals. According to an embodiment of the invention, the integration circuit 822 comprises at least a pair of feedback resistors R6 and R8, each being respectively coupled between a pair of output nodes and a pair of input nodes of the amplifier circuit 800, for feeding the pair of amplified output signals S_{Out1} and S_{Out2} (which may be regarded as a pair of feedback signals) back to the pair of input nodes of the amplifier circuit 800. The integration circuit 822 further comprises fully differential error amplifiers 830 and 832. The fully differential error amplifiers 830 and 832 accompanying with the feedback resistors R6 and R8 and the capacitors C7 and C8, and C9 and C10 form a two-order integration circuit. The first order integration circuit comprises a first integrator 827, which is formed by the fully differential error amplifier 830 and corresponding capacitors and resistors, and the second order integration circuit comprises a second integrator 828, which is formed by the fully differential error amplifier 832 and corresponding capacitors and resistors. Since the integrators 827 and 828 are hierarchically connected, the first integrator 827 and the second integrator 828 together form a two-order integrating path and the first integrator 827 alone forms an one-order integrating path

According to an embodiment of the invention, the first integrator (or, the first order integration circuit) is coupled to the pair of input nodes of the amplifier circuit 800 for generating a first pair of integration signals at a pair of differential output nodes V′a and V′b according to the pair of differential input signals S_{Inp} and S_{Inn} and the pair of amplified output signals S_{Out1} and S_{Out2} which are fed back to the pair of input nodes. The second integrator (or, the second order integration circuit) is coupled to the pair of differential output nodes V′a and V′b of the first integrator and corresponding clock input nodes for receiving the clock signals CLK1 and CLK1′, and generates a second pair of integration signals at a pair of differential output nodes V′e and V′f according to the first pair of integration signals and the clock signals CLK1 and CLK1′.

The comparator circuit 824 comprises comparators 836 and 838. The comparator 836 is coupled to the pair of differential output nodes V′e and V′f of the second integrator for comparing the second pair of integration signals to generate the comparison signal S_{Cmp1}. The comparator 838 is coupled to the pair of differential output nodes V′a and V′b at nodes V′g and V′h for comparing the first pair of integration signals to generate the comparison signal S_{Cmp2}. The logic circuit 826 comprises a NOR gate 840 and an AND gate 841, for respectively performing logic operations on the comparison signals S_{Cmp1} and S_{Cmp2} to generate the modulation signals S_{Mod1} and S_{Mod2}. It should be noted that the invention should not be limited to the NOR gate and AND gate as shown in FIG. 21. FIG. 5A and FIG. 5B show the equivalent logic gates for the NOR gate and AND gate. In some embodiments of the invention, the NOR gate 840 and an AND gate 841 as shown in FIG. 21 may be replaced by the logic gates shown in FIG. 5A and FIG. 5B, or other logic gates. Therefore, the invention scope should not be limited to the NOR gate 840 and an AND gate 841 as shown in FIG. 21.

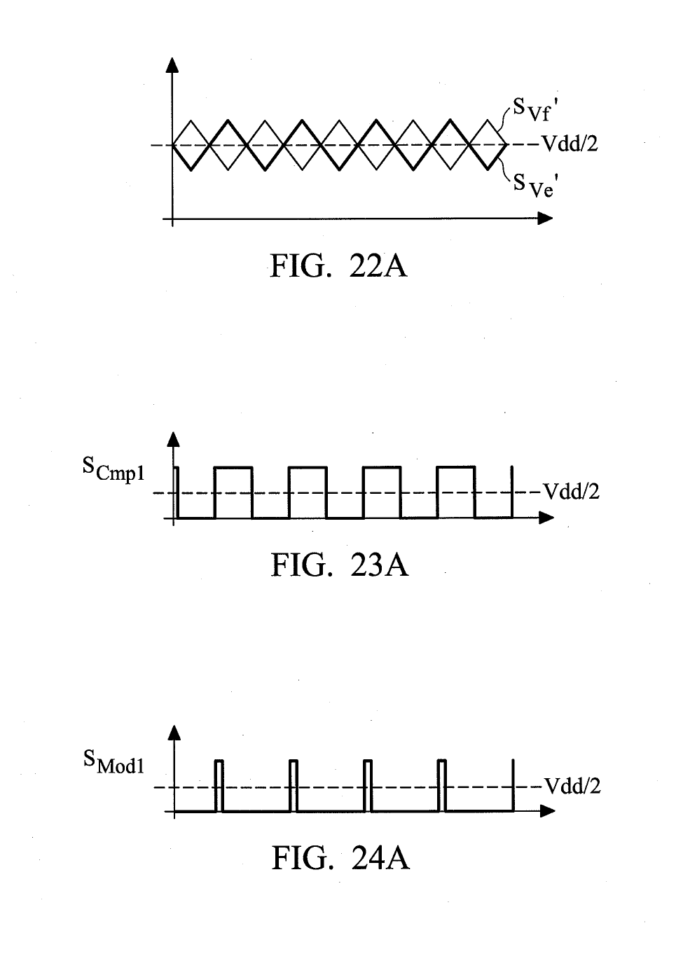

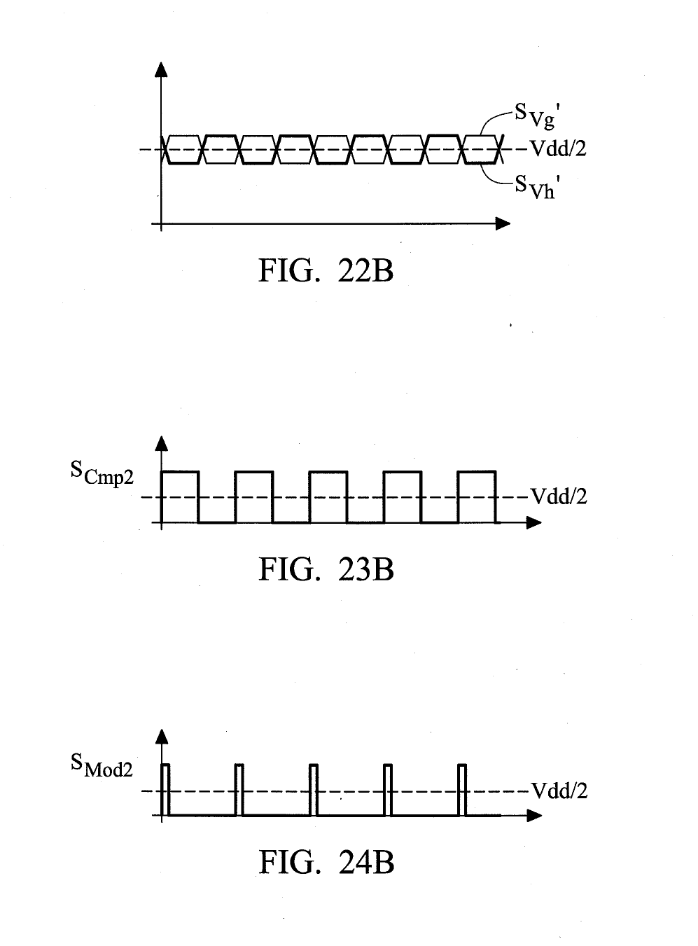

FIG. 22A shows exemplary waveforms of the second pair of integration signals S_{V′e} and S_{V′f} at the differential output nodes V′e and V′f according to an embodiment of the invention. FIG. 22B shows exemplary waveforms of the first pair of integration signals S_{V′g} and S_{V′h} at the nodes V′g and V′h according to an embodiment of the invention. The comparators 836 and 838 respectively compares the levels of the integration signals S_{V}'ₑ and S_{V′f}, and S_{V′g} and S_{V′h}, and generate the comparison signal S_{Cmp1} as shown in FIG. 23A and the comparison signal S_{Cmp2} as shown in FIG. 23B. The logic circuit performs NOR and AND logic operations on the comparison signals S_{Cmp1} and S_{Cmp2}, and obtains the modulation signal S_{Mod1} as shown in FIG. 24A and the modulation signal S_{Mod2} as shown in FIG. 24B.

According to an embodiment of the invention, FIG. 22 to FIG. 24 show the waveforms of output signals of each circuit when there is no alternating current (AC) signal input to the amplifier circuit, wherein no AC signal input means the level difference between the differential input signals S_{Inp}, and S_{Inn} at the differential input nodes is 0. As shown in FIG. 24A and FIG. 24B, both the modulation signals S_{Mod1} and S_{Mod2} comprise pulses which are very narrow in width.

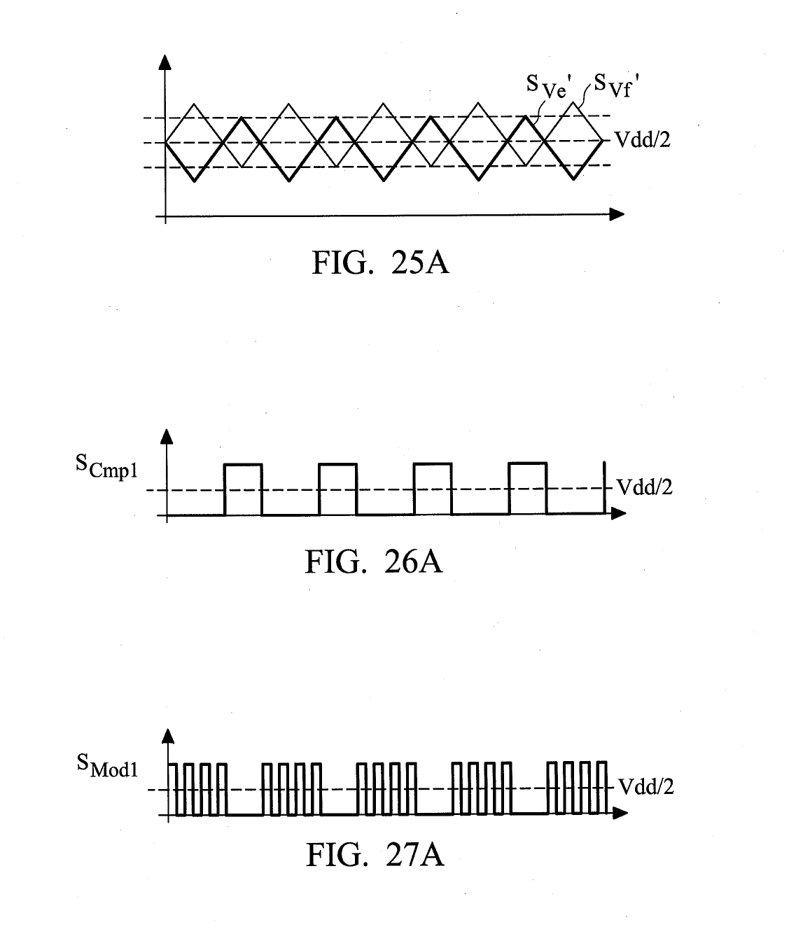

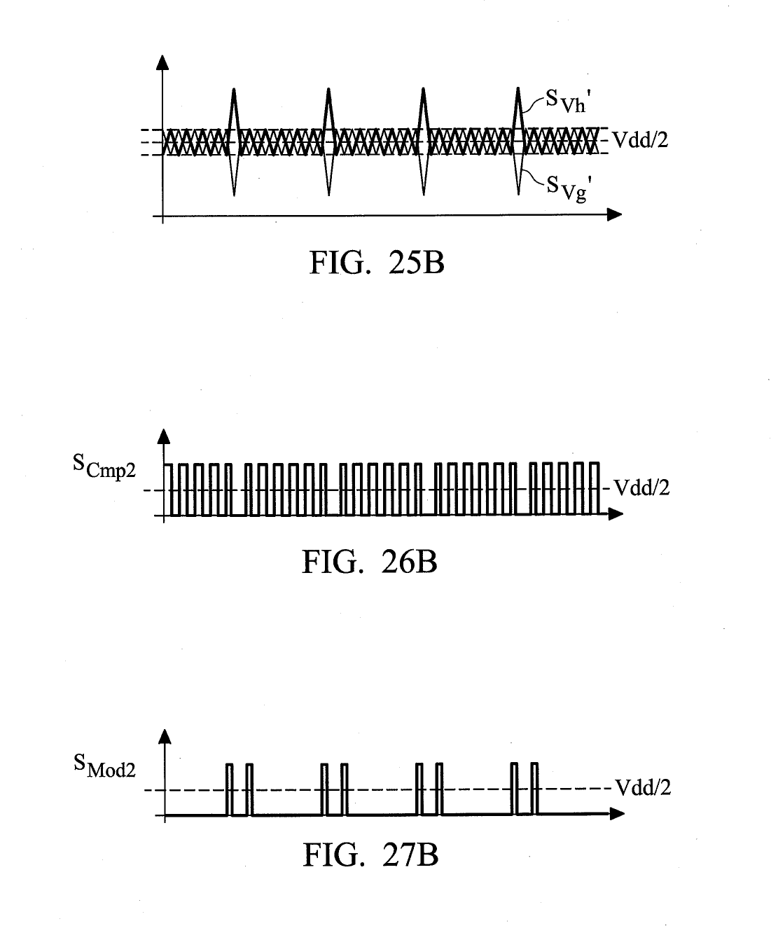

FIG. 25A shows exemplary waveforms of the second pair of integration signals S_{V′e} and S_{V′f} according to another embodiment of the invention. FIG. 25B shows exemplary waveforms of the first pair of integration signals S_{V′g} and S_{V′h} according to another embodiment of the invention. In this embodiment, there is an AC signal input to the circuits and a level of the input signal S_{Inn} is greater than that of the input signal S_{Inp} (in other words, the level difference between the input signals S_{Inn} and S_{Inp} is greater than 0). FIG. 26A shows the waveform of the comparison signal S_{Cmp1} generated based on the integration signals S_{V′d} and S_{V′f} as shown in FIG. 25A. FIG. 26B shows the waveform of the comparison signal S_{Cmp2} generated based on the integration signals S_{V′g} and S_{V′h} as shown in FIG. 25B. Finally, the logic circuit performs NOR and AND logic operations on the comparison signals S_{Cmp1} and S_{Cmp2} and obtains the modulation signal S_{Mod1} as shown in FIG. 27A and the modulation signal S_{Mod2} as shown in FIG. 27B.

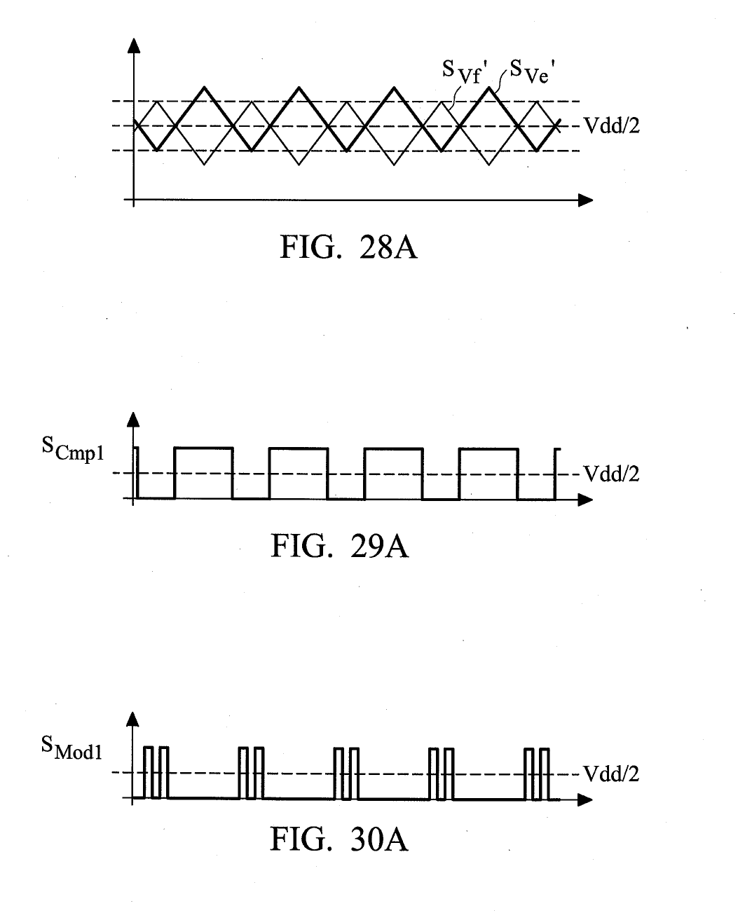

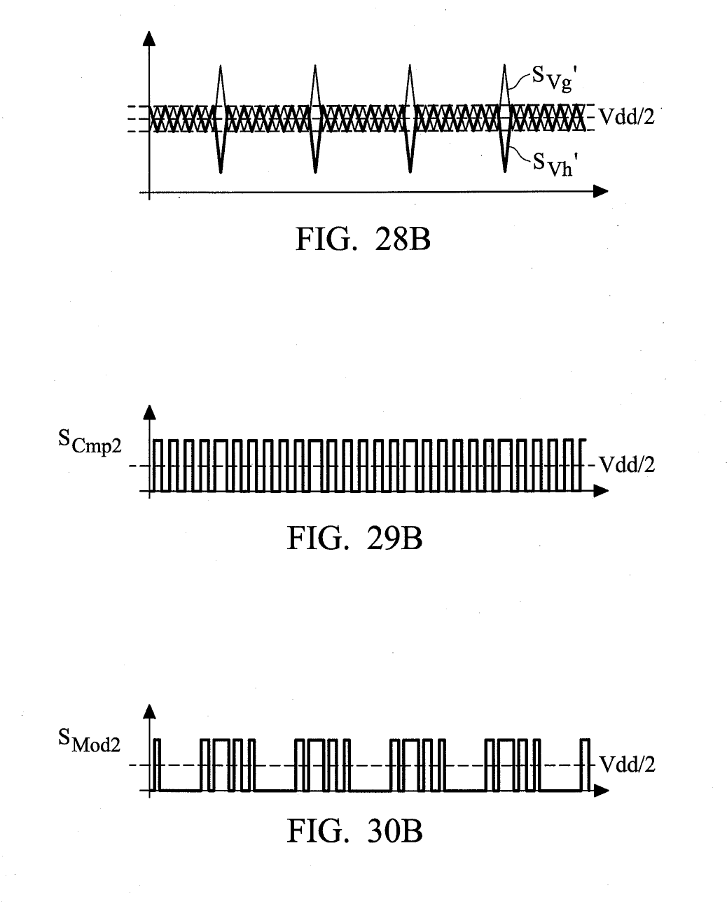

FIG. 28A shows exemplary waveforms of the second pair of integration signals S_{V′e} and S_{V′f} according to another embodiment of the invention. FIG. 28B shows exemplary waveforms of the first pair of integration signals S_{V′g} and S_{V′h} according to another embodiment of the invention. In this embodiment, there is an AC signal input to the circuits and a level of the input signal S_{Inp} is greater than that of the input signal S_{Inn} (in other words, the level difference between the input signals S_{Inp} and S_{Inn} is greater than 0). FIG. 29A shows the waveform of the comparison signal S_{Cmp1} generated based on the integration signals S_{V′e} and S_{V′f} as shown in FIG. 28A. FIG. 29B shows the waveform of the comparison signal S_{Cmp2} generated based on the integration signals S_{V′g} and S_{V′h} as shown in FIG. 28B. Finally, the logic circuit performs NOR and AND logic operations on the comparison signals S_{Cmp1} and S_{Cmp2} and obtains the modulation signal S_{Mod1} as shown in FIG. 30A and the modulation signal S_{Mod2} as shown in FIG. 30B.

From FIG. 24A and FIG. 24B, FIG. 27A and FIG. 27B and FIG. 30A and FIG. 30B, it can be noted that different from the pulse width modulation (PWM) signals outputted by the conventional class D amplifier, the modulation signals S_{Mod1} and S_{Mod2} outputted by the proposed amplifier circuit may comprise narrow pulses. In this manner, the EMI of the amplified output signal can be greatly reduced while the signal level (i.e. strength) of the modulation signals can remain unchanged because the modulation signals can have a narrower pulse width than in a conventional class D amplifier.

In addition, as shown in FIG. 1, the PWM modulator in the conventional class D amplifier requires an extra triangle wave generator to generate a triangle wave with a predetermined frequency. The triangle wave generator is generally not easy to design. However, as shown in FIG. 22A, FIG. 25A, and FIG. 28A, the triangle waves have been generated in the modulation procedure of the modulation signal generating circuit and have been carried onto the integration signals S_{V′e} and S_{V′f}. Therefore, in the proposed amplifier circuit, the extra triangle wave generator is not required. As long as the clock signals CLK1 and CLK1′ are input, the modulation signals can be generated.

In addition, as compared with the architecture as shown in FIG. 2 and FIG. 4, only a pair of complimentary clock signals is required in the architecture as shown in FIG. 20 and FIG. 21. Therefore, the timing control of the clock signal is much easier since there is no need to control the phase difference td as discussed above. In addition, since there is only two integrator required in the architecture as shown in FIG. 20 and FIG. 21, the circuit area is greatly reduced as compared with the architecture as shown in FIG. 2 and FIG. 4 and the signal distortion in the pair of amplified output signals is also greatly reduced as compared with the architecture as shown in FIG. 2 and FIG. 4.

Note that second integrator 828 in FIG. 21 may also be disposed in the lower integrating path between the nodes V′a and V′b and the nodes V′g and V′h when the nodes V′a and V′b is directly connected to the nodes V′e and V′f, and thus the invention should not be limited to the structure as shown in FIG. 21.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. An amplifier circuit, comprising:
a modulation signal generating circuit, generating a pair of modulation signals according to a pair of differential input signals and a plurality of clock signals;
a driving stage circuit, generating a pair of driving signals according to the pair of modulation signals; and
an output stage circuit, generating a pair of amplified output signals according to the pair of driving signals.

2. The amplifier circuit as claimed in claim 1, wherein the clock signals comprise a first clock signal and a second clock signal, and wherein the first clock signal and the second clock signal are complementary clock signals.

3. The amplifier circuit as claimed in claim 1, wherein the clock signals comprise a first clock signal and a second clock signal, and wherein there is a phase difference between the first clock signal and the second clock signal.

4. The amplifier circuit as claimed in claim 3, wherein the phase difference is greater than a sum of a propagation delay of the amplifier circuit and a dead time of the output stage circuit.

5. The amplifier circuit as claimed in claim 1, wherein the modulation signal generating circuit comprises:
an integration circuit, generating a plurality of pairs of integration signals according to the pair of differential input signals and the clock signals;
a comparator circuit, comparing the pairs of integration signals to generate a pair of comparison signals; and
a logic circuit, generating the pair of modulation signals according to logic operation results of the pair of comparison signals.

6. The amplifier circuit as claimed in claim 5, wherein the integration circuit comprises:
a pair of feedback resistors, coupled between a pair of output nodes outputting the pair of amplified output signals and a pair of input nodes receiving the pair of differential input signals and for feeding the pair of amplified output signals back to the pair of input nodes;
a first integrator, coupled to the pair of input nodes for generating a first pair of integration signals according to the pair of differential input signals and the pair of amplified output signals fed back to the pair of input nodes; and
a second integrator, coupled to the first integrator for generating a second pair of integration signals according to the first pair of integration signals, a first clock signal and a second clock signal,
wherein the first clock signal and the second clock signal are complementary clock signals, and
wherein the comparator circuit compares the first pair of integration signals and the second pair of integration signals to generate the pair of comparison signals.

7. The amplifier circuit as claimed in claim 5, wherein the integration circuit comprises:
a pair of feedback resistors, coupled between a pair of output nodes outputting the pair of amplified output signals and a pair of input nodes receiving the pair of differential input signals and for feeding the pair of amplified output signals back to the pair of input nodes;
a first integrator, coupled to the pair of input nodes for generating a first pair of integration signals according to the pair of differential input signals and the pair of amplified output signals fed back to the pair of input nodes;
a second integrator, coupled to the first integrator for generating a second pair of integration signals according to the first pair of integration signals and a first clock signal; and
a third integrator, coupled to the first integrator for generating a third pair of integration signals according to the first pair of integration signals and a second clock signal,
wherein a phase difference between the first clock signal and the second clock signal is greater than a sum of a propagation delay of the amplifier circuit and a dead time of the output stage circuit, and
wherein the comparator circuit compares the second pair of integration signals and the third pair of integration signals to generate the pair of comparison signals.

8. The amplifier circuit as claimed in claim 6, wherein the comparator circuit comprises a first comparator and a second comparator, the first comparator compares the second pair of integration signals to generate a first comparison signal, and the second comparator compares the first pair of integration signals to generate a second comparison signal.

9. The amplifier circuit as claimed in claim 7, wherein the comparator circuit comprises a first comparator and a second comparator, the first comparator compares the second pair of integration signals to generate a first comparison signal, and the second comparator compares the third pair of integration signals to generate a second comparison signal.

10. The amplifier circuit as claimed in claim 5, wherein the integration circuit comprises:
a pair of feedback resistors, coupled between a pair of output nodes outputting the pair of amplified output signals and a pair of input nodes receiving the pair of differential input signals and for feeding the pair of amplified output signals back to the pair of input nodes;
a first integrator, coupled to the pair of input nodes for generating a first pair of integration signals according to the pair of differential input signals and the pair of amplified output signals fed back to the pair of input nodes;
a second integrator, coupled to the first integrator for generating a second pair of integration signals according to the first pair of integration signals, a reference voltage and a first clock signal; and
a third integrator, coupled to the first integrator for generating a third pair of integration signals according to the first pair of integration signals, the reference voltage and a second clock signal,
wherein a phase difference between the first clock signal and the second clock signal is greater than a sum of a propagation delay of the amplifier circuit and a dead time of the output stage circuit, and
wherein the comparator circuit compares the second pair of integration signals and the third pair of integration signals to generate the pair of comparison signals.

11. The amplifier circuit as claimed in claim 5, wherein the logic circuit comprises a NOR gate and an AND gate, the NOR gate performs a NOR logic operation on the pair of comparison signals to generate a first modulation signal; and the AND gate performs an AND logic operation on the pair of comparison signals to generate a second modulation signal.

12. A modulation signal generating circuit, comprising:
an integration circuit, comprising a plurality of hierarchically connected integrators to form a plurality of integrating paths for generating a plurality of pairs of integration signals according to a pair of differential input signals and a plurality of clock signals;
a comparator circuit, comparing the pairs of integration signals to generate a pair of comparison signals; and
a logic circuit, generating a pair of modulation signals according to logic operation results of the pair of comparison signals.

13. The modulation signal generating circuit as claimed in claim 12, wherein the integration circuit comprises:
a first integrator, coupled to a pair of input nodes for generating a first pair of integration signals according to the pair of differential input signals and a pair of feedback signals; and
a second integrator, coupled to the first integrator for generating a second pair of integration signals according to the first pair of integration signals, a first clock signal and a second clock signal,
wherein the first clock signal and the second clock signal are complementary clock signals,
wherein the first integrator forms an one-order integrating path and the first integrator and the second integrator together form a two-order integrating path, and
wherein the comparator circuit comprises a first comparator and a second comparator, the first comparator compares the second pair of integration signals to generate a first comparison signal, and the second comparator compares the first pair of integration signals to generate a second comparison signal.

14. The modulation signal generating circuit as claimed in claim 12, wherein the integration circuit comprises:
a first integrator, coupled to a pair of input nodes for generating a first pair of integration signals according to the pair of differential input signals and a pair of feedback signals;
a second integrator, coupled to the first integrator for generating a second pair of integration signals according to the first pair of integration signals and a first clock signal; and
a third integrator, coupled to the first integrator for generating a third pair of integration signals according to the first pair of integration signals and a second clock signal,
wherein there is a phase difference between the first clock signal and the second clock signal,
wherein the first integrator and the second integrator together form a first two-order integrating path and the first integrator and the third integrator together form a second two-order integrating path, and
wherein the comparator circuit comprises a first comparator and a second comparator, the first comparator compares the second pair of integration signals to generate a first comparison signal, and the second comparator compares the third pair of integration signals to generate a second comparison signal.

15. The modulation signal generating circuit as claimed in claim 12, wherein the second integrator is further coupled to a reference voltage for generating the second pair of integration signals further according to the reference voltage, and the third integrator is further coupled to the reference voltage for generating the third pair of integration signals further according to the reference voltage.

16. A modulation signal generating circuit, comprising:
a first order integration circuit, generating a first pair of integration signals according to a pair of differential input signals;
a second order integration circuit, generating a second pair of integration signals according to the first pair of integration signals and a plurality of clock signals;
a comparator circuit, generating a pair of comparison signals according to the first and the second pair of integration signals; and
a logic circuit, generating a pair of modulation signals according to logic operation results of the pair of comparison signals.

17. The modulation signal generating circuit as claimed in claim 16, wherein the clock signals comprises a first clock signal and a second clock signal which are complementary clock signals, the first order integration circuit comprises:
a first integrator, coupled to a pair of input nodes for receiving the pair of differential input signals, and
the second order integration circuit comprises:
a second integrator, coupled to a pair of differential output nodes of the first integrator, a first clock input node for receiving the first clock signal and a second clock input node for receiving the second clock signal,
and the comparator circuit comprises:
a first comparator, coupled to a pair of differential output nodes of the second integrator for receiving the second pair of integration signals; and
a second comparator, coupled to a pair of differential output nodes of the first integrator for receiving the first pair of integration signals.

18. The modulation signal generating circuit as claimed in claim 16, wherein the pair of clock signals comprises a first clock signal and a second clock signal having a phase difference therebetween, the first order integration circuit comprises:
a first integrator, coupled to a pair of input nodes for receiving the pair of differential input signals,
the second order integration circuit further generates a third pair of integration signals according to the first pair of integration signals and the clock signals and comprises:
a second integrator, coupled to a pair of differential output nodes of the first integrator and a first clock input node for receiving the first clock signal, and generating the second pair of integration signals according to the first pair of integration signals and the first clock signal; and
a third integrator, coupled to the pair of differential output nodes of the first integrator and a second clock input node for receiving the second clock signal, and generating the third pair of integration signals according to the first pair of integration signals and the second clock signal,
and the comparator circuit generates the pair of comparison signals further according to the third pair of integration signals and comprises:
a first comparator, coupled to a pair of differential output nodes of the second integrator for receiving the second pair of integration signals; and
a second comparator, coupled to a pair of differential output nodes of the third integrator for receiving the third pair of integration signals.

19. The modulation signal generating circuit as claimed in claim 16, wherein the logic circuit comprises a NOR gate and an AND gate, the NOR gate performs a NOR logic operation on the pair of comparison signals to generate a first modulation signal; and the AND gate performs an AND logic operation on the pair of comparison signals to generate a second modulation signal.

20. The modulation signal generating circuit as claimed in claim 18, wherein the second integrator is further coupled to a reference voltage for generating the second pair of integration signals further according to the reference voltage, and the third integrator is further coupled to the reference voltage for generating the third pair of integration signals further according to the reference voltage.
